(19) United States
(12) Patent Application Publication
(10) Pub. No.: US 2020/0233470 A1
(43) Pub. Date: Jul. 23, 2020

(54) COOLING DEVICE FOR ELECTRONIC DEVICES

(71) Applicant: Scott Eric Gallacher, Draper, UT (US)

(72) Inventor: Scott Eric Gallacher, Draper, UT (US)

(21) Appl. No.: 16/745,974

(22) Filed: Jan. 17, 2020

Related U.S. Application Data
(60) Provisional application No. 62/794,494, filed on Jan. 18, 2019.

(51) Int. Cl. G06F 1/20; H01L 23/433

(52) U.S. Cl. CPC G06F 1/203; H01L 23/433

(57) ABSTRACT

There is a cooling device for electronic devices. The cooling device comprises: a frame body having an array of apertures disposed therethrough, from a front of the frame body to a back of the frame body, the array of apertures separated from each other by a framework; a top slot disposed along a top end of the frame body, parallel to a top edge thereof; a bottom pair of tabs coupled to a bottom end of the frame body and extending frontward orthogonally from the bottom end of the frame body, and; a fluid absorbent strip coupled to the front of the frame body and disposed on the frame body and through the top slot.

### CROSS-REFERENCE TO RELATED APPLICATIONS

This invention claims priority under 35 U.S.C. § 120, to the U.S. Provisional Patent Application No. 62/794,494, by Scott Eric Gallacher, filed on Jan. 18, 2019, which is incorporated by reference herein in its entirety.

### FIELD OF THE INVENTION

The present invention relates to cooling devices, specifically cooling devices for hand-held electronic devices.

### DESCRIPTION OF THE RELATED ART

In the related art, it has been known that handheld electronic devices may he cooled to prevent overheating. The external temperature of a handheld electronic device, for example, a smart phone, a smart watch, a virtual reality device, a tablet, etc., may be skin temperature limited for a user's comfort level and safety. In a handheld electronic device, the heat generated by the electronic chips located inside the handheld electronic device is distributed across the handheld electronic device's surface to reduce hot spots at the surface of the handheld electronic device. Natural convection is used to dissipate the heat generated in the handheld electronic device to the ambient environment. However, in some cases, natural convection may not provide sufficient heat dissipation to maintain the surface temperature of the handheld electronic device at or below skin temperature without impacting the performance of the hand held electronic device, e.g., due to reducing clock rate to reduce heat generation in the handheld electronic device.

Electronic devices, and in particular personal electronic devices such as Smartphones, tablets, and laptop computers, have gone through major evolutions in the past decade. The devices themselves have become smaller and smaller, while at the same time, utilizing more and more processing power, advanced communications electronics, and fewer moving parts. Electronic circuitry and components generate heat during operation. Removal of this heat is critical for stable operation and long operating lifetimes. As circuit packaging densities increase, efficient heat removal has become even more critical. More notable is the fact that when the operating temperature of these devices increase, the performance of the device drops, either purposely by design, or naturally because of the inherent characteristics of solid state electronics. Many devices have built in safe modes that completely shut down the processors and other heat generating components if the operating temperature gets too high.

The use and development of smaller, faster, more powerful computer chips and electronic components in mobile phones, computers, laptops, tablets, etc. has caused a dramatic increase in the power, run time and heat generation in these components. The increased power and heat generation be controlled to prevent overheating and damage to the components. This overheating also causes hotspots and hot areas on the surface of the device thereby causing discomfort or injury to the human user and therefore there is a need to manage this heat. This heat control is done by either removing the heat by various means or “throttling back the power and speed of the components to reduce the generated heat. Reducing the speed and power of the components is not preferable since this creates inefficiencies; prolonged wait times for results, reduced download speeds, etc. Therefore materials are needed to both absorb or store this generated heat and subsequently rapidly remove or conduct heat away from the components.

Heat is removed from electronic devices by various means such as cooling fans, heat sinks, and bimetallic cooling arrangements, to name a few. Cooling fans require their own circuitry and thus increase the complexity and expense of the electronic apparatus. Heat sinks may be either of the metallic type such as comprised of aluminum or of the conformable type.

Handheld mobile computing devices such as smart phones and tablet computers are designed to have a reduced volume to comply with expected user form factor. Furthermore, handheld devices typically have unibody chassis which are held by a user's hands (as opposed to, for example, laptop computers which typically have separate chassis for the dis play and the keyboard), and thus have temperature limits based on user comfort levels. The capabilities of mobile device components are currently limited by these chassis temperature limits.

Thus, handheld devices typically utilize passive cooling solutions—fans are undesirable because in addition to the increase the system chassis volume, they produce unwanted effects such as fan noise and introduce moving parts to the device. With increasingly more processing power expected from mobile devices, an effective passive cooling solution is needed to allow for more powerful components to be utilized while preserving the expected user form factor.

Some improvements have been made in the field. Examples of references related to the present invention are described below in their own words, and the supporting teachings of each reference are incorporated by reference herein:

U.S. Pat. No. 5,060,114, issued to Feinberg et al., discloses a conformable, gel-like pad, preferably of silicone, with a thermally conductive additive conducts heat away from a packaged electronic power device with which it is in contact. Formed by adding particles of a thermally conductive material such as aluminum powder, nickel, aluminum oxide, iron oxide, beryllium oxide, silver, etc., to a mixture of silicone resins and curing agents poured into a mold, the molded pad can be formed to accommodate virtually any geometry and size of electronic component to provide a custom-fit at little cost. A thin, solid sheet of a thermally conductive metal such as aluminum positioned in contact with a surface of the conformable pad further increases heat removal. Another embodiment contemplates a metallic foil disposed in contact with a surface of or within the conformable pad and extending therefrom which can be coupled to a heat sink or to neutral ground potential for radiation shielding. A metallic radiation shield box may be used as a mold for forming the conformable pad and to form a combination EMI/RFI radiation shield and heat transfer device for an electronic component disposed within the box and in contact with the conformable pad.

U.S. Patent Application Publication No.: 2002/0112499, by Goldfine, discloses An evaporative cooling article, the evaporative cooling article including a non-woven fabric, the non-woven fabric being water absorbent and exposed to atmosphere, the evaporative cooling article effective for exerting an evaporative cooling effect on a liquid held within a container when the container is in contact with the evaporative cooling article.

U.S. Patent Application Publication No.: 2017/0023267, by Strauss, discloses a device for cooling the surface of an object or the skin of a person or animal comprising a plurality of evaporator fins, each having a substantially planar horizontal portion for making contact with an object to be cooled, one or more vertical portions attached to or continuing from the horizontal portion that extends upward there from, and a fabric layer disposed on a surface of the vertical portion. The device includes a support member comprised of one or more parts that connect the plurality of evaporator tins into a larger structure, and can include means to urge the horizontal portions of the evaporator fin assembly against a surface to be cooled. The device can also be embodied as one or more pieces of fabric with a plurality of convoluted evaporator fins adhered to it.

U.S. Patent Application Publication No.: 2018/0220553, by Saeidi et al., discloses an apparatus and method of the disclosure provides a cooling mechanism for a handheld electronic device. The cooling mechanism includes a heat sink and an evaporative cooling mechanism. The evaporative cooling mechanism includes liquid retaining structures. The liquid retaining structures are located in proximity to the at least one IC of the handheld electronic. Each liquid retaining structure is coated with a temperature sensitive polymer that act as hydrophilic when the temperature of the surface of the handheld electronic device is below a threshold temperature. To maintain the temperature of the surface of the handheld electronic device below the threshold temperature, the temperature sensitive polymer act as hydrophobic and evaporates the liquid stored in the liquid retaining structures to the atmosphere surrounding the handheld electronic device when the temperature of the surface of the electronic device is above the threshold temperature.

The inventions heretofore known suffer from a number of disadvantages which include, but are not limited to: requiring electricity, being noisy, being difficult to use, requiring cords, being difficult to recharge, requiring special tools to operate or recharge, not being multipurpose, being heavy, being expensive, requiring multiple versions to tit multiple device brands/models, not being removable, and not being waterproof.

What is needed is a cooling device that solves one or more of the problems described herein and/or one or more problems that may come to the attention of one skilled in the art upon becoming familiar with this specification.

### SUMMARY OF THE INVENTION

The present invention has been developed in response to the present state of the art, and in particular, in response to the problems and needs in the art that have not yet been fully solved by currently available cooling devices. Accordingly, the present invention has been developed to provide a cooling device for hand-held electronic devices.

In one embodiment of the invention, there is a cooling device for electronic devices. The cooling device may comprise a frame body that may have an array of apertures that may be disposed therethrough, from a front of the frame body to a back of the frame body. The array of apertures may be separated from each other by a framework. A top slot may be disposed along a top end of the frame body, and may be parallel to a top edge thereof. A bottom pair of tabs may be coupled to a bottom end of the frame body and/or extending frontward orthogonally from the bottom end of the frame body, and/or a fluid absorbent strip may be coupled to the front of the frame body and/or disposed on the frame body and/or through the top slot.

In another embodiment of the invention, the top slot may be bounded by a top pair of tabs that may be coupled to a top end of the frame body and/or extending frontward orthogonally from the top end of the frame body. The bottom pair of tabs may form a boundary of a bottom slot that may be disposed along a bottom end of the frame body, parallel to a bottom edge thereof. The array of apertures may include a main aperture that may be disposed through a center portion of the frame body, and/or a plurality of apertures that may be disposed around the main aperture. Each aperture may be smaller than the main aperture.

In addition, in one embodiment of the invention, the apertures may be regular polygons. The top and/or bottom pairs of tabs may extend frontward the same distance. The fluid absorbent strip may be removably coupled to the frame body. The top slot may extend through the frame body from a front of the frame body to a back of the frame body.

More, in another embodiment of the invention, each tab may be disposed along a corner of the frame body and/or each tab may include a slot-portion spaced from the frame body. The absorbent strip may have a length greater than twice a length of the frame body and/or a width equal to a width of the frame body. Each tab may be flag-shaped.

Reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussion of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize that the invention can be practiced without one or more of the specific features or advantages of a particular embodiment. In other instances, additional features and advantages may be recognized in certain embodiments that may not be present in all embodiments of the invention.

These features and advantages of the present invention will become more fully apparent from the following description and appended claims, or may be learned by the practice of the invention as set forth hereinafter.

### BRIEF DESCRIPTION OF THE DRAWINGS

In order for the advantages of the invention to be readily understood, a more particular description of the invention briefly described above will be rendered by reference to specific embodiments that are illustrated in the appended drawing(s). It is noted that the drawings of the invention are not to scale. The drawings are mere schematics representations, not intended to portray specific parameters of the invention. Understanding that these drawing(s) depict only typical embodiments of the invention and are not, therefore, to be considered to be limiting its scope, the invention will be described and explained with additional specificity and detail through the use of the accompanying drawing(s), in which:

FIG. 1 is a front perspective view of a cooling device for electronic devices, according to one embodiment of the invention;

FIG. 2 is a front view of a cooling device for electronic devices showing evaporation from a a cooling electronic device, according to one embodiment of the invention;

FIG. 3 is a side view of a cooling device for electronic devices showing evaporation from a cooling electronic device, according to one embodiment of the invention;

FIG. 4 is a front perspective view of a frame body of a cooling device for electronic devices, according to one embodiment of the invention;

FIG. 5 is a top plan view of a frame body of a cooling device for electronic devices, according to one embodiment of the invention;

FIG. 6 is a front perspective view of a frame body of a cooling device for electronic devices, according to one embodiment of the invention; and

FIG. 7 is a top plan view of a frame body of a cooling device for electronic devices, according to one embodiment of the invention.

### DETAILED DESCRIPTION OF THE INVENTION

For the purposes of promoting an understanding of the principles of the invention, reference will now be made to the exemplary embodiments illustrated in the drawing(s), and specific language will be used to describe the same. It will nevertheless be understood that no limitation of the scope of the invention is thereby intended. Any alterations and further modifications of the inventive features illustrated herein, and any additional applications of the principles of the invention as illustrated herein, which would occur to one skilled in the relevant art and having possession of this disclosure, are to be considered within the scope of the invention.

Reference throughout this specification to an “embodiment,” an “example” or similar language means that a particular feature, structure, characteristic, or combinations thereof described in connection with the embodiment is included in at least one embodiment of the present invention. Thus, appearances of the phrases an “embodiment,” an “example,” and similar language throughout this specification may, but do not necessarily, all refer to the same embodiment, to different embodiments, or to one or more of the figures. Additionally, reference to the wording “embodiment,” “example” or the like, for two or more features, elements, etc. does not mean that the features are necessarily related, dissimilar, the same, etc.

Each statement of an embodiment, or example, is to be considered independent of any other statement of an embodiment despite any use of similar or identical language characterizing each embodiment. Therefore, where one embodiment is identified as “another embodiment,” the identified embodiment is independent of any other embodiments characterized by the language “another embodiment.” The features, functions, and the like described herein are considered to be able to be combined in whole or in part one with another as the claims and/or art may direct, either directly or indirectly, implicitly or explicitly.

As used herein, “comprising,” “including,” “containing,” “is,” “are,” “characterized by,” and grammatical equivalents thereof are inclusive or open-ended terms that do not exclude additional unrecited elements or method steps. “Comprising” is to be interpreted as including the more restrictive terms “consisting of” and “consisting essentially of.”

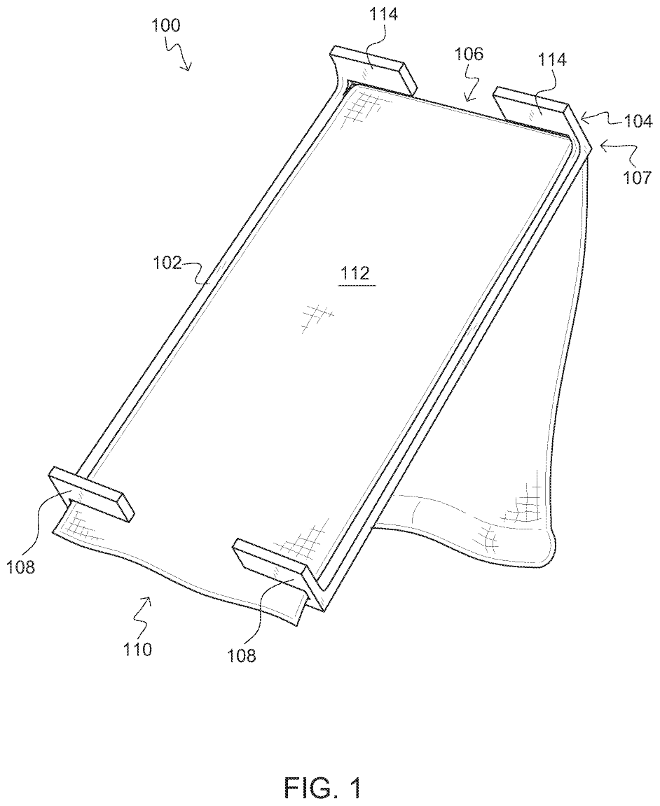

FIG. 1 is a front perspective view of a cooling device for electronic devices, according to one embodiment of the invention. There is shown a cooling device 100 that includes a frame body 102. The frame body includes a top slot 104 disposed along a top end 106 of the frame body 102 at a top edge 107. A bottom pair of tabs 108 are coupled to the frame body 102 at a bottom end 110 of the frame body 102. The cooling device 100 also includes a fluid absorbent strip 112 disposed on the frame body 102 through the top slot 104 and through the bottom pair of tabs 108. There is also shown a top pair of tabs 114 coupled to the frame body 102.

As illustrated, the frame body 102 provides a support for components of the cooling device 100. The frame body 102 is generally smooth and light so as to not interfere with operation of the cooling device 100 (esp. sliding the fluid absorbent strip 112, wherein a strip 112 is used that is longer than the frame). The frame body 102 may be of plastic, metal, ceramic, wood, or the like or composites thereof. The frame body 102 will generally be shaped similar to a shape of a handheld electronic device(s) intended to be cooled thereby, such that the fluid absorbent strip 112 may cover all or substantially most of a backside thereof and be supported adjacent thereto by the frame body 102.

The frame body 102 will generally be sized to be a little larger than a largest handheld electronic device intended to be cooled thereby. As a non-limiting example, wherein the cooling device 100 is intended for use with smartphones, it may be rectangular in shape, as shown, and be sized (height and width) to receive the largest mass-produced smartphone currently on the market, with pairs of tabs 108 and 114 that extend approximately half as thick or more as the thickest mass-produced smartphone currently on the market. Accordingly, a single cooling device 100 may be mass-produced for a single device type, and that single cooling device 100 will be suitable for every single brand/model of that type.

The illustrated frame body 102 includes the top slot 104. The top slot 104 is bounded by the top pair of tabs 114 and the top end 106 of the frame body 102 and is formed thereby. The top slot 104 is parallel to the top edge 107. As illustrated, the top slot 104 is a long, narrow aperture or slit that allows for insertion of an object. The fluid absorbent strip 112 is disposed through the top slot 104 below the top pair of tabs 114.

As illustrated, the top slot 104 is shaped and sized to allow the strip 112 to pass therethrough in a flat configuration so that the strip 112 may lay flat against the frame body 102 and, during operation, between the frame 102 and a handheld electronic device to be cooled. The illustrated top slot 104 extends almost the entire width of the frame body 102 so that a large fluid absorbent strip 112 may be disposed thereto to maximize cooling effect from direct contact with the evaporating strip 112.

The bottom pair of tabs 108 are coupled to the frame body 102 opposite the top pair of tabs 114. The illustrated fluid absorbent strip 112 is also disposed below the bottom pair of tabs 108. The bottom pair of tabs 108 and the top pair of tabs 114 are identical. The illustrated pairs of tabs 108 and 114, respectively, are small flaps attached to the frame body 102 and projecting therefrom. The pairs of tabs 108 and 114 may be removably and/or slidably coupled to the frame body 102. The bottom pair of tabs 108 extends frontward orthogonally from the bottom end 110 of the frame body 102, and the top pair of tabs 114 extends frontward orthogonally from the top end 106 of the frame body 106. The pairs of tabs 108 and 114 are flag-shaped. Accordingly, the pairs of tabs 108 and 114, respectively, may be used, or manipulated, to hold the fluid absorbent strip 112 in place.

As illustrated, the fluid absorbent strip 112 is a covering disposed on the frame body 102. The fluid absorbent strip 112 may be removably and/or slidably coupled to the frame body 102. The fluid absorbent strip 112 is removably coupled to the frame body 102 so that it may be removed for washing, soaking, wetting, etc. The fluid absorbent strip 112 is sized to cover the frame body 102 and drape over the top edge 107 of the frame body 102. As a result, the fluid absorbent strip 112 is longer than the frame body 102.

The fluid absorbent strip 112 may have a variety of sizes and shapes. For instance, a width and/or length of the fluid absorbent strip 112 may be larger than a width or length the frame body 102, smaller than a width or length the frame body 112, or equal to a width or length of the frame body 102. Likewise, the fluid absorbent strip 112 may be rectangular, square, circular, oval, pentagonal, hexagonal, and so on. The fluid absorbent strip 112 may be comprised of layers. The fluid absorbent strip 112 may be comprised of layers of moisture wicking fabric, such as, but not limited to: one hundred percent cotton, nylon polyester, jersey blends, polyester, cotton polyester blends, polypropylene, rayon, polyamide, and combinations thereof. The fluid absorbent strip 112 may be comprised of a loosely braided or twisted cord or tape of cotton. The fluid absorbent strip 112 may be comprised of microfiber.

In operation of one embodiment of the invention, a user soaks the fluid absorbent strip 112 in a fluid, such as water. The user then rings out the fluid absorbent strip 112 to remove excess fluid, while also maintaining moisture within the strip 112. The user covers the frame body 102 of the cooling device 100 by sliding the fluid absorbent strip 112 through the top pair of tabs 114 and down through the bottom pair of tabs 108. The fluid absorbent strip 112 is longer than the frame body so that it hangs downward from the top edge 107 of the frame body 102. A handheld electronic device may be placed on a portion of the fluid absorbent strip 112 on the frame body 102. Then, the handheld electronic device may be covered by fluid absorbent strip 112 by draping the hanging portion of the strip 112 over the top pair of tabs 114. Heat from the adjacent handheld electronic device is transferred to the fluid absorbent strip 112 resulting in evaporation of fluid from the fluid absorbent strip 112 and a reduction in temperature of the handheld electronic device.

Additionally, a user may adjust the strip during operation to allow a heated region of the strip to dangle or otherwise be out of contact with the electronic device while disposing a region of the cloth that had not been in contact with the electronic device adjacent the electronic device so that it may further cool the device while the heated region is cooling off.

According to another non-limiting embodiment, there frame body is foldable. Such may include one or more hinges disposed about a midpoint of the frame body. The frame body may be in two pieces that are coupled together by hinges. The frame body may include a narrowed region about a midpoint thereof about which the frame body can fold (e.g. the hinge is a leaf spring coupling the top and bottom portions of the frame body).

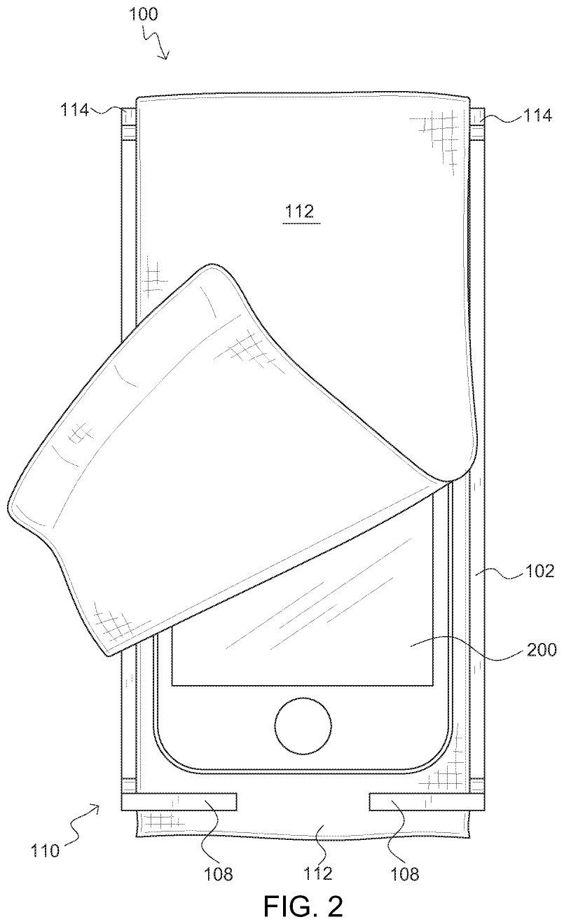

FIG. 2 is a front view of a cooling device for electronic devices showing evaporation from a cooling electronic device, according to one embodiment of the invention. There is shown a cooling device 100 with a frame body 102. The frame body 102 includes a bottom pair of tabs 108 coupled to the frame body 102 at a bottom end 110 of the frame body 102. The frame body 102 also includes a fluid absorbent strip 112 and a top pair of tabs 114. The top pair of tabs 114 are disposed on the frame body 102 opposite the bottom pair of tabs 108, and the fluid absorbent strip 112 is disposed on the frame body 102 from the top pair of tabs 114 to the bottom pair of tabs 108. A handheld electronic device 200 is disposed on the fluid absorbent strip 112 and on the frame body 102 thereby. The fluid absorbent strip 112 is also partially disposed over the handheld electronic device 200 and thereby partially covers the handheld electronic device 200.

As shown, the cooling device 100 includes the frame body 102. The fluid absorbent strip 112 is disposed on the frame body 102 beneath the bottom pair of tabs 108 and beneath the top pair of tabs 114. As a result, the pairs of tabs 108 and 114, respectively, help to secure the fluid absorbent strip 112 in place to prevent slipping, etc.

The illustrated handheld electronic device 200 is disposed on a portion of the fluid absorbent strip 112 disposed on the frame body 102. A portion of the fluid absorbent strip 112 is draped over the top pair of tabs 114 and is partially covering the handheld electronic device 200. The handheld electronic device 200 may be any device, such as, but not limited to: a smartphone, a tablet, an ipod, an mp3 player, and so on. The fluid absorbent strip 112 may be sized to have a length greater than twice a length of the frame body 102 and a width equal to a width of the frame body 102.

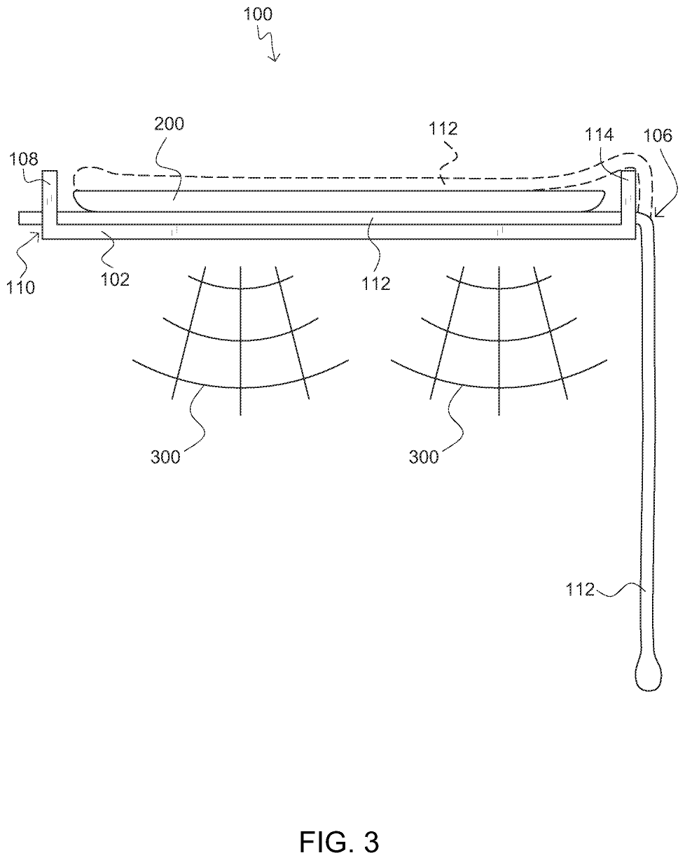

FIG. 3 is a side view of a cooling device for electronic devices showing evaporation from a cooling electronic device, according to one embodiment of the invention. There is shown a cooling device 100 including a frame body 102. A bottom pair of tabs 108 is disposed at a bottom end 110 of the frame body 102, and a top pair of tabs 114 are disposed at a top end 106 of the frame body 102 opposite the bottom pair of tabs 108. A fluid absorbent strip 112 is disposed on the frame body 102, and a handheld electronic device 200 is disposed on the fluid absorbent strip 112. Accordingly, the fluid absorbent strip 112 and frame body 102 provide evaporation 300 to the handheld electronic device 200.

The illustrated cooling device 100 includes the frame body 102 with the top pair of tabs 114 and the bottom pair of tabs 108 extending therefrom. The fluid absorbent strip 112 is disposed on the frame body 102. In one embodiment of the invention, the fluid absorbent strip 112 may hang downward from the top end 106 of the frame body 102. In another embodiment of the invention, the fluid absorbent strip 112 may drape over the top pair of tabs 102 and cover the handheld electronic device 200 and provide evaporation 300 thereby. As shown, the fluid absorbent strip 112 flares out at an end. The fluid absorbent strip 112 may include one or more flared portions that may be disposed at one or more ends of the fluid absorbent strip 112 to provide for gripping by hand and such flared portions may be thicker than the top slot (See e.g., FIG. 1, Item 104) so that the fluid absorbent strip 112 is prevented from slipping all the way through the top slot (See e.g., FIG. 1, Item 104). As a result, the illustrated cooling device 100 facilitates in the cooling of a handheld electronic device 200 by operation of evaporation 300 of a moistened absorbent strip 112 that is disposed on the frame body 102 and through the slot (See e.g., FIG. 1, Item 106).

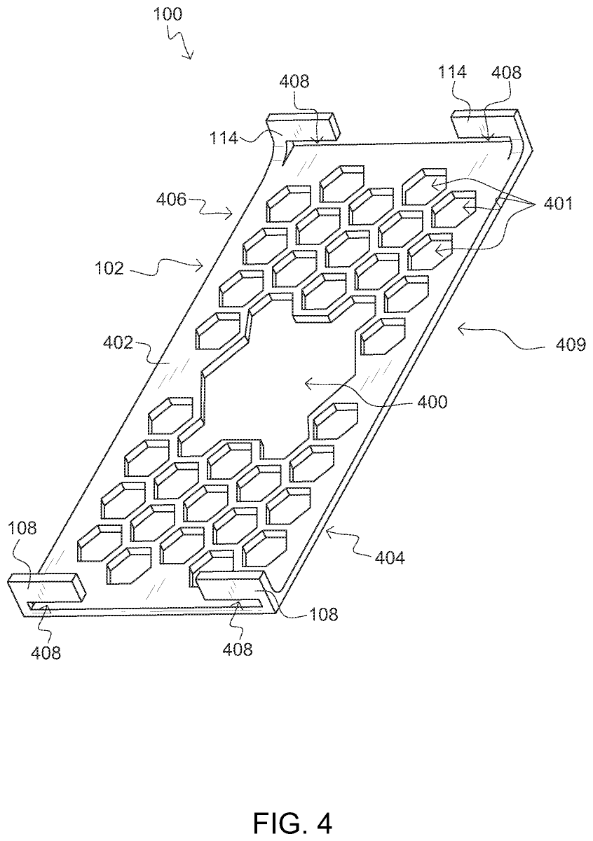

FIG. 4 is a front perspective view of a frame body of a cooling device for electronic devices, according to one embodiment of the invention. There is shown a cooling device 100 with a fame body 102. The frame body 102 includes an array of apertures 409 including a main aperture 400 disposed through a center portion of the main body 102, and a plurality of apertures 401 disposed about the main aperture 400. The apertures 400 and 401, respectively, are disposed through the frame body 102 from a front of frame body 402 to a back of frame body 404. The apertures 400 and 401, respectively, are disposed about the frame body 102 to provide a framework 406 of the frame body 102. In addition, the frame body 102 includes a pair of bottom tabs 108 and a pair of top tabs 114, each pair being coupled to the frame body so that a slot portion 408 is disposed between the tab pairs 108 and 114, respectively, and the frame body 102.

The illustrated array of apertures 409 provide fluid communication between the backside of the fluid absorbent strip (See e.g., FIG. 3, Item 112) and the ambient air, thereby increasing evaporation and distributing the evaporative action across a larger portion of the strip (See e.g., FIG. 3, Item 112) than would occur if there were not an array of apertures 409. As shown, the array 409 includes a main aperture 400 disposed therethrough from the front of frame body 402 to the back of frame body 404. The main aperture 400 is centrally located on the frame body 102. A plurality of apertures 401 surround the main aperture 400 and are also disposed through the frame body 102 from the front of frame body 402 to the back of frame body 404. Each aperture of the plurality of apertures 401 are smaller than the main aperture 400. As shown, the apertures 400 and 401 are regular polygons. For instance, the illustrated plurality of apertures 401 are hexagonal.

The illustrated main aperture 400 is surrounded by framework 409 that provides support therearound. The large main aperture 400 also provides space for centrally positioned accessories, such as but not limited to stands, mounts, grips, clips, hard points, and the like so that the accessory may protrude through the main aperture and thus not interfere with flat contact between the fluid absorbent strip (See e.g., FIG. 3, Item 112) and the backside of the handheld electronic device (See e.g., FIG. 2, Item 200) at other backside regions of the handheld electronic device (See e.g., FIG. 2, Item 200).

The illustrated array 409 includes a framework 406 between the apertures 409, 400 and 401 that provide support for the fluid absorbent strip (See e.g., FIG. 3, Item 112) and handheld electronic device (See e.g., FIG. 2, Item 200) and that keep the strip (See e.g., FIG. 3, Item 112) from sagging, as cooling effects are maximized when the strip (See e.g., FIG. 3, Item 112) is in direct physical contact with the handheld electronic device (See e.g., FIG. 2, Item 200). The framework 406 provides support to the frame body 102 and separates the apertures 400 and 401, respectively. The framework 406 also allows for evaporation (See e.g., FIG. 3, Item 300) of fluid from the fluid absorbent strip (See e.g., FIG. 3, Item 112).

As illustrated, the slot portion 408 is a space disposed between the pairs of tabs 108 and 114, respectively, and the frame body 102. Accordingly, the slot portion 408 is bounded by the pairs of tabs 108 and 114, respectively, so that the pairs of tabs 108 and 114, each form a boundary. The pairs of tabs 108 and 114, may be identical and equally spaced along the frame body 102 so that each slot portion 408 is also identical in size and shape. In one embodiment, the fluid absorbent strip (See e.g., FIG. 3, Item 112) may be disposed through the slot portion 408 near the top pair of tabs 114, coupled to a front of the frame body 402, and disposed through the slot portion 408 of the bottom pair of tabs 108.

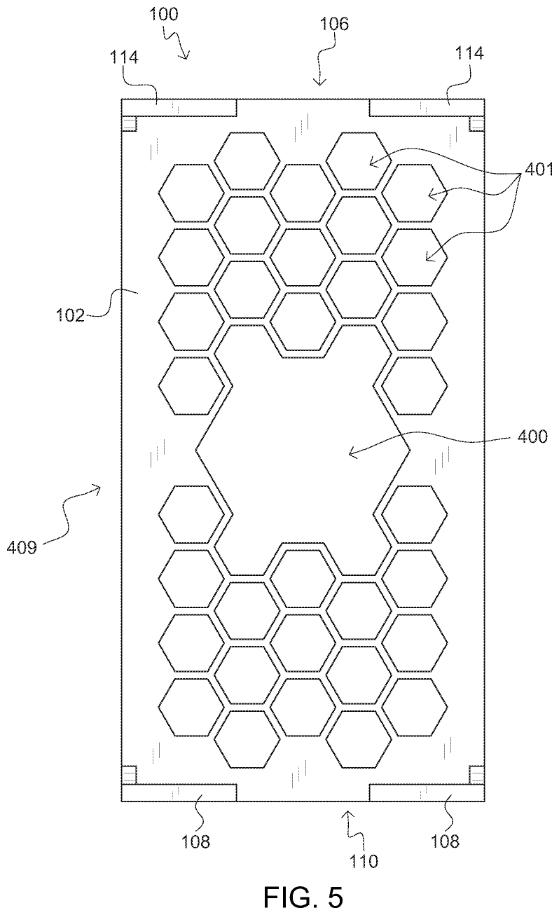

FIG. 5 is a top plan view of a frame body of a cooling device for electronic devices, according to one embodiment of the invention. There is shown a cooling device 100 including a frame body 102. The frame body 102 includes an array of apertures 409 with main aperture 400 and a plurality of apertures 401 disposed about the main aperture 400. The frame body 102 also includes a bottom pair of tabs 108 disposed along a bottom end 110 of the frame body 102, and a top pair of tabs 114 disposed opposite the bottom pair of tabs 108 along a top end 106 of the frame body 102.

The illustrated pairs of tabs 108 and 114, respectively, are identical. The bottom pair of tabs 108 extends frontward orthogonally from a bottom end 110 of the frame body 102, and the top pair of tabs 114 extends orthogonally from a top end 106 of the frame body 102. In addition, the pairs of tabs 108 and 114, respectively, extend from corners of the frame body 102 toward a like tab. For instance, a top tab 114 extends from a corner of the frame body 102 toward another top tab 114, and a bottom tab 108 extends from a corner of the frame body toward another bottom tab 108. The top pair of tabs 114 and the bottom pair of tabs 108 each extend frontward the same distance.

The illustrated tabs 108 and 114 extend substantially orthogonally (so as to provide support to help prevent the handheld electronic device (See e.g., FIG. 2, Item 200) from slipping off the frame body 102 while being held vertically) from a bottom end 110 of the frame body 102. The illustrated tabs are a pairs of tabs 108 and 114, are each positioned opposite each other, side-to-side, at the bottom end 110 and the top end 106, respectively, of the frame body 102. The illustrated pairs of tabs 108 and 114 are integral to the frame body 102, but may be attached or coupled thereto. The tabs 108 and 114 may also be movable and/or selectably positionable where desired. The gap between the tabs 108 and 114 allows for structures that may be coupled to a bottom of the handheld electronic device (See e.g., FIG. 2, Item 200) to remain coupled thereto, such as but not limited to headphone jacks, charging cables, mounting structures, and the like and combinations thereof.

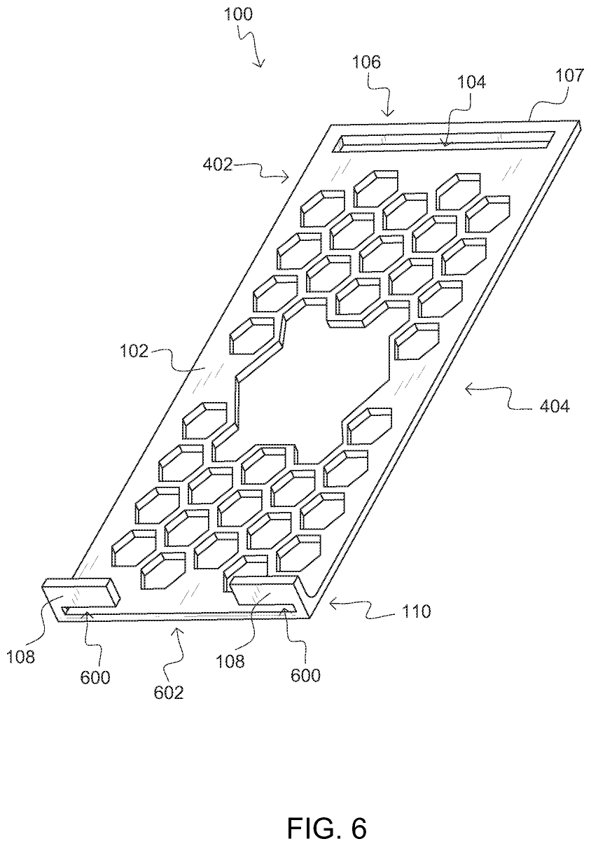

FIG. 6 is a front perspective view of a frame body of a cooling device for electronic devices, according to one embodiment of the invention. There is shown a cooling device 100. The cooling device 100 includes a frame body 102. A top slot 104 is disposed along a top end 106, and near a top edge 107, of the frame body 102. A pair of bottom tabs 108 are coupled to the frame body 102 at an end of the frame body 102 opposite the top slot 104. A bottom slot 600 is disposed between the bottom pair of tabs 108 and a bottom edge 602 of the frame body 102.

As shown, a top slot 104 is disposed at a top end 106 of the frame body 102. The top slot 104 is disposed along the top end 106 parallel to a top edge 107 of the frame body 102. The top slot 104 extends through the frame body 102 from a front of frame body 402 to a back of frame body 404. A length and/or volume of the top slot 104 may be sized to accommodate sliding a fluid absorbent strip (See e.g., FIG. 3, Item 112) therethrough.

A bottom slot 600 is shown disposed at an end of the frame body 102 opposite the top slot 104. The bottom slot 600 is disposed below the bottom pair of tabs 108 and above the frame body 102. The bottom pair of tabs 108 forms a boundary of the bottom slot 600 disposed along a bottom end 110 of the frame body 102 parallel to a bottom edge thereof 602. The bottom slot 600 may have a length sized to allow a fluid absorbent strip (See e.g., FIG. 3, Item 112) to slide there through.

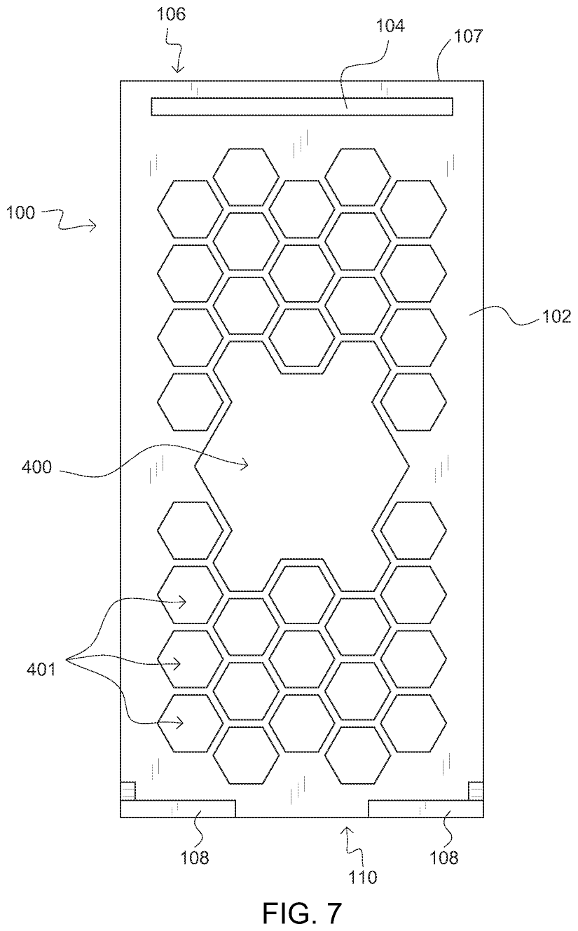

FIG. 7 is a top plan view of a frame body of a cooling device for electronic devices, according to one embodiment of the invention. There is shown a cooling device 100 with a frame body 102. A top slot 104 is disposed at a top end 106 and near a top edge 107 of the frame body 102. A bottom pair of tabs 108 are disposed at a bottom end 110 of the frame body 102 opposite the top slot 104. The frame body 102 also includes a main aperture 400 disposed through the frame body 102, and a plurality of apertures 401 each disposed about the main aperture 400 and through the frame body 102.

The illustrated bottom pair of tabs 108 extend frontward orthogonally from a bottom end 110 of the frame body 102. The illustrated top slot 104 runs parallel to a top edge 107 of the frame body. Accordingly, in one embodiment, a fluid absorbents strip (See e.g., FIG. 3, Item 112) may be disposed through the top slot 104, over the frame body 102 and over apertures 400 and 401, respectively, and under the bottom pair of tabs 108.

It is understood that the above-described embodiments are only illustrative of the application of the principles of the present invention. The present invention ay be embodied in other specific forms without departing rom its spirit or essential characteristics. The described embodiment is to be considered in all respects only as illustrative and not restrictive. The scope of the invention is, therefore, indicated by the appended claims rather than by the foregoing description. An changes which come within the meaning and range of equivalency of the claims are to be embraced within their scope.

For example, although the array of apertures includes a large main aperture disposed centrally to the frame body, the main aperture may be disposed anywhere on the frame body. Also, the array of apertures may be devoid of a main aperture. Too, the apertures may have any size and/or shape for providing evaporation to the fluid absorbent strip through the frame body.

Additionally, although the figures illustrate pairs of tabs disposed at ends of the frame body, the tabs may be disposed anywhere along the frame body. In addition, the tabs may have any orientation to the frame body. For instance, the tabs may extend toward, or away from, a front of the main body. More, there may be any number of tabs coupled to the frame body, and the tabs may or may not help to form a slot.

It is also envisioned that there may be a plurality of slots through the frame body. Slots may be disposed between a frame body and one or more tabs. There may be a slot at a top and a slot at a bottom of the frame body so that a long strip of absorbent material may be pulled through and the slots may extend only through the tabs and may be open at the tabs so that the fluid absorbent strip may be removed by bunching the strip up between the tabs.

It is expected that there could be numerous variations of the design of this invention. An example is that the apertures could have any size, shape and/or spacing to provide a evaporation to the fluid absorbent strip through the frame body. Likewise, the framework may have any configuration tor supporting the frame body and accessories. As another example, the frame body may have any size and/or shape configured to support a handheld electronic device and fluid absorbent strip, such as, but not limited to: rectangular, square, oval, pentagonal and hexagonal.

Finally, it is envisioned that the components of the device may be constructed of a variety of materials, such as, but not limited to: plastic, metal, textiles, rubber, PVC, and so on. For example, the frame body may be injection molded, 3-D printed, or laser cut. Moreover, the frame body may be flexible or rigid, depending on the material(s) used.

Thus, while the present invention has been fully described above with particularity and detail in connection with what is presently deemed to be the most practical and preferred embodiment of the invention, it will be apparent to those of ordinary skill in the art that numerous modifications, including, but not limited to, variations in size, materials, shape, form, fraction and manner of operation, assembly and use may be made, without departing from the principles and concepts of the invention as set forth in the claims. Further, it is contemplated that an embodiment may be limited to consist of or to consist essentially of one or more of the features, functions, structures, methods described herein.

What is claimed is:

1. A cooling device for electronic devices, comprising:
a. a frame body having an array of apertures disposed therethrough, from a front of the frame body to a back of the frame body, the array of apertures separated from each other by a framework;
b. a top slot disposed along a top end of the frame body, parallel to a top edge thereof;
c. a bottom pair of tabs coupled to a bottom end of the frame body and extending frontward orthogonally from the bottom end of the frame body, and;
d. a fluid absorbent strip coupled to the front of the frame body and disposed on the frame body and through the top slot.

2. The cooling device of claim 1, wherein the top slot is bounded by a top pair of tabs coupled to a top end of the frame body and extending frontward orthogonally from the top end of the frame body.

3. The cooling device of claim 1, wherein the bottom pair of tabs form a boundary of a bottom slot disposed along a bottom end of the frame body, parallel to a bottom edge thereof.

4. The cooling device of claim 1, wherein the array of apertures includes:
a. a main aperture disposed through a center portion of the frame body; and
b. a plurality of apertures disposed around the main aperture, each smaller than the main aperture.

5. The cooling device of claim 1, wherein the apertures are regular polygons.

6. The cooling device of claim 1, wherein the top and bottom pairs of tabs extend frontward the same distance.

7. The cooling device of claim 1, wherein the fluid absorbent strip is removably coupled to the frame body.

8. The cooling device of claim 1, wherein the top slot extends through the frame body from a front of the frame body to a back of the frame body.

9. The cooling device of claim 2, wherein each tab is disposed along a corner of the frame body and each tab includes a slot-portion spaced from the frame body.

10. The cooling device of claim 1, wherein the absorbent strip has a length greater than twice a length of the frame body and a width equal to a width of the frame body.

11. The cooling device of claim 2, wherein each tab is flag-shaped.

12. A cooling device for electronic devices, comprising:
a. a frame body having an array of apertures disposed therethrough, from a front of the frame body to a back of the frame body, the array of apertures separated from each other by a framework;
b. a top slot disposed along a top end of the frame body, parallel to a top edge thereof;
c. a bottom pair of tabs coupled to a bottom end of the frame body and extending frontward orthogonally from the bottom end of the frame body, and;
d. a fluid absorbent strip coupled to the front of the frame body and disposed on the frame body and through the top slot
e. wherein the top slot is bounded by a top pair of tabs coupled to a top end of the frame body and extending frontward orthogonally from the top end of the frame body.

13. The cooling device of claim 12, wherein the bottom pair of tabs form a boundary of a bottom slot disposed along a bottom end of the frame body, parallel to a bottom edge thereof.

14. The cooling device of claim 13, wherein the array of apertures includes:
a. a main aperture disposed through a center portion of the frame body; and
b. a plurality of apertures disposed around the main aperture, each smaller than the main aperture.

15. The cooling device of claim 14, wherein the apertures are regular polygons.

16. The cooling device of claim 15, wherein the top and bottom pairs of tabs extend frontward the same distance.

17. The cooling device of claim 16, wherein the fluid absorbent strip is removably coupled to the frame body.

18. The cooling device of claim 17, wherein the top slot extends through e frame body from a front of the frame body to a back of the frame body.

19. The cooling device of claim 18, wherein each tab is disposed along a corner of the frame body and each tab includes a slot-portion spaced from the frame body.

20. A cooling device for electronic devices, comprising:
a. a frame body having an array of apertures disposed therethrough, from a front of the frame body to a back of the frame body, the array of apertures separated from each other by a framework, being regular polygons and including:
i. a main aperture disposed through a center portion of the frame body; and
ii. a plurality of apertures disposed around the main aperture, each smaller than the main aperture;
b. a top slot disposed along a top end of the frame body, parallel to a top edge thereof, bounded by a top pair of tabs coupled to a top end of the frame body and extending frontward orthogonally from the top end of the frame body;
c. a bottom pair of tabs coupled to a bottom end of the frame body and extending frontward orthogonally from the bottom end of the frame body the same distance as the top pair of tabs, forming a boundary of a bottom slot disposed along a bottom end of the frame body, parallel to a bottom edge thereof, each tab being disposed along a corner of the frame body and including a slot-portion spaced from the frame body, each tab being flag-shaped, and;
d. a fluid absorbent strip removably coupled to the front of the frame body and disposed on the frame body and through the top slot, and having a length greater than twice a length of the frame body and a width equal to a width of the frame body.
